(19) United States
(12) Patent Application Publication
(10) Pub. No.: US 2024/0162285 A1
(43) Pub. Date: May 16, 2024

(54) SEMICONDUCTOR DEVICE AND MANUFACTURING METHOD OF SEMICONDUCTOR DEVICE

(71) Applicant: FUJI ELECTRIC CO., LTD., Kanagawa (JP)

(72) Inventors: Tohru SHIRAKAWA, Matsumoto-city (JP); Yasunori AGATA, Matsumoto-city (JP); Kaname MITSUZUKA, Matsumoto-city (JP)

(21) Appl. No.: 18/472,197

(22) Filed: Sep. 21, 2023

(30) Foreign Application Priority Data
Nov. 15, 2022 (JP) 2022-182712

(51) Int. Cl. H01L 29/06; H01L 21/265; H01L 21/268; H01L 27/06; H01L 29/40; H01L 29/739; H01L 29/861

(52) U.S. Cl. CPC H01L 29/0623; H01L 21/26513; H01L 21/268; H01L 27/0664; H01L 29/404; H01L 29/7397; H01L 29/8613

(57) ABSTRACT

Provided is a semiconductor device including an active portion arranged below an upper surface electrode and an edge termination structure portion arranged between the upper surface electrode and an end side of a semiconductor substrate in a top view, in which the active portion includes an active collector region, the edge termination structure portion includes an edge collector region, and an integrated value of a carrier concentration of the active collector region in a depth direction is larger than an integrated value of a carrier concentration of the edge collector region in the depth direction. An upper end position of the active collector region in the depth direction and an upper end position of the edge collector region in the depth direction may differ.

The contents of the following patent application(s) are incorporated herein by reference:
NO. 2022-182712 filed in JP on Nov. 15, 2022

### BACKGROUND

### 1. Technical Field

The present invention relates to a semiconductor device and a manufacturing method of a semiconductor device.

### 2. Related Art

Conventionally, there has been known a semiconductor device including an active region formed with a transistor portion and an edge region enclosing the active region (see, for example, Patent Document 1). There is also known a configuration in which a P− layer and a P+ layer are stacked on a back surface of a semiconductor substrate (see, for example, Patent Document 2).
Patent Document 1: Japanese Patent Application Publication No. 2022-016169
Patent Document 2: Japanese Patent Application Publication No. 2004-311481

### BRIEF DESCRIPTION OF THE DRAWINGS

FIG. 1 illustrates a top view showing an example of a semiconductor device 100 according to one embodiment of the present invention.

FIG. 2 illustrates an enlarged view of a region D in FIG. 1.

FIG. 3 illustrates a view showing an example of a cross section e-e in FIG. 2.

FIG. 4 illustrates a view showing an example of a cross section b-b in FIG. 1.

FIG. 5 illustrates a view showing a distribution example of a dopant concentration and a carrier concentration on a line f-f of FIG. 4 in a depth direction.

FIG. 6 illustrates a view showing a distribution example of a dopant concentration and a carrier concentration on a line g-g of FIG. 4 in the depth direction.

FIG. 7 illustrates a view showing another example of the distribution of the dopant concentration and the carrier concentration in an active collector region 22.

FIG. 8 illustrates a view showing an example of a carrier concentration distribution in the active collector region 22 and a part of a buffer region 20.

FIG. 9A illustrates a view showing another example of the cross section b-b.

FIG. 9B illustrates a view showing another example of the cross section b-b.

FIG. 10 illustrates a flowchart showing an example of a manufacturing method of the semiconductor device 100.

FIG. 11 illustrates a view showing an example of a relationship between an annealing temperature of the semiconductor substrate 10 and an activation rate of a dopant.

### DESCRIPTION OF EXEMPLARY EMBODIMENTS

Hereinafter, the present invention will be described through embodiments of the invention, but the following embodiments do not limit the invention according to claims. In addition, not all of the combinations of features described in the embodiments are essential to the solution of the invention.

As used herein, one side in a direction parallel to a depth direction of a semiconductor substrate is referred to as “upper” and the other side is referred to as “lower”. One surface of two principal surfaces of a substrate, a layer, or other member is referred to as an upper surface, and the other surface is referred to as a lower surface. “Upper” and “lower” directions are not limited to a direction of gravity, or a direction in which a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate a height direction with respect to the ground. Note that a +Z axis direction and a −Z axis direction are directions opposite to each other. When the Z axis direction is described without describing the signs, it means that the direction is parallel to the +Z axis and the −Z axis.

In the present specification, orthogonal axes parallel to an upper surface and lower surface of a semiconductor substrate are referred to as the X axis and the Y axis. Further, an axis perpendicular to the upper surface and the lower surface of the semiconductor substrate is referred to as the Z axis. In the present specification, the direction of the Z axis may be referred to as the depth direction. Further, in the present specification, a direction parallel to the upper surface and the lower surface of the semiconductor substrate may be referred to as a horizontal direction, including the X axis direction and the Y axis direction.

A region from a center of the semiconductor substrate in the depth direction to the upper surface of the semiconductor substrate may be referred to as an upper surface side. Similarly, the region from the center of the semiconductor substrate in the depth direction to the lower surface of the semiconductor substrate may be referred to as a lower surface side.

In the present specification, a case where a term such as “same” or “equal” is mentioned may include a case where an error due to a variation in manufacturing or the like is included. The error is, for example, within 10%.

In the present specification, a conductivity type of a doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting a conductivity type of the N type, or a semiconductor presenting a conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking polarities of charges into account. As an example, when the donor concentration is N_{D} and the acceptor concentration is N_{A}, the net doping concentration at any position is given as N_{D}-N_{A}. In the present specification, the net doping concentration may be simply referred to as the doping concentration.

The donor has a function of supplying electrons to a semiconductor. The acceptor has a function of receiving electrons from the semiconductor. The donor and acceptor are not limited to the impurities themselves. For example, a VOH defect which is a combination of a vacancy (V), oxygen (O), and hydrogen (H) existing in the semiconductor functions as the donor that supplies electrons. In the present specification, the VOH defect may be referred to as a hydrogen donor.

In the present specification, bulk donors of the N type are distributed throughout the semiconductor substrate. The bulk donor is a dopant donor substantially uniformly contained in an ingot during the manufacture of the ingot from which the semiconductor substrate is made. The bulk donor of this example is an element other than hydrogen. The dopant of the bulk donor is, for example, phosphorus, antimony, arsenic, selenium, or sulfur, but the present invention is not limited to these. The bulk donor of this example is phosphorus. The bulk donor is also contained in the P type region. The semiconductor substrate may be a wafer cut out from a semiconductor ingot, or may be a chip obtained by singulating the wafer. The semiconductor ingot may be manufactured by any of a Chokralski method (CZ method), a magnetic field applied Chokralski method (MCZ method), or a float zone method (FZ method). The ingot of this example is manufactured by the MCZ method. An oxygen concentration contained in the substrate manufactured by the MCZ method is 1×10¹⁷ to 7×10¹⁷/cm³. The oxygen concentration contained in the substrate manufactured by the FZ method is 1×10¹⁵ to 5×10¹⁶/cm³. When the oxygen concentration is high, hydrogen donors tend to be easily generated. A chemical concentration of a bulk donor distributed throughout the semiconductor substrate may be used for the bulk donor concentration, which may also be a value from 90% to 100% of the chemical concentration. Further, as the semiconductor substrate, a non-doped substrate not containing a dopant such as phosphorus may be used. In that case, the bulk donor concentration (DO) of the non-doped substrate is, for example, 1×10¹⁰/cm³ or more and 5×10¹²/cm³ or less. The bulk donor concentration (DO) of the non-doped substrate is preferably 1×10¹¹/cm³ or more. The bulk donor concentration (DO) of the non-doped substrate is preferably 5×10¹²/cm³ or less. Note that each concentration in the present invention may be a value at room temperature. As the value at room temperature, a value at 300 K (Kelvin) (about 26.9° C.) may be used as an example.

In the present specification, a description of a P+ type or an N+ type means a higher doping concentration than that of the P type or the N type, and a description of a P− type or an N-type means a lower doping concentration than that of the P type or the N type. Further, in the present specification, a description of a P++ type or an N++ type means a higher doping concentration than that of the P+ type or the N+ type. In the present specification, a unit system is the SI base unit system unless otherwise stated in particular. Although a unit of length may be expressed in cm, calculations may be carried out after conversion to meters (m).

A chemical concentration in the present specification indicates an atomic density of an impurity measured regardless of an electrical activation state. The chemical concentration can be measured by, for example, secondary ion mass spectrometry (SIMS). The net doping concentration described above can be measured by capacitance-voltage profiling (CV profiling). Furthermore, a carrier concentration measured by a spreading resistance profiling method (SRP method) may be set as the net doping concentration. The carrier concentration measured by the CV profiling or the SRP method may be set as a value in a thermal equilibrium state. Furthermore, in a region of an N type, the donor concentration is sufficiently higher than the acceptor concentration, and therefore, the carrier concentration in the region may be set as the donor concentration. Similarly, in a region of a P type, the carrier concentration in the region may be set as the acceptor concentration. In the present specification, the doping concentration of the N type region may be referred to as the donor concentration, and the doping concentration of the P type region may be referred to as the acceptor concentration.

When a concentration distribution of the donor, acceptor, or net doping has a peak in a region, a value of the peak may be set as the concentration of the donor, acceptor, or net doping in the region. In a case where the concentration of the donor, acceptor, or net doping is substantially uniform in a region, or the like, an average value of the concentration of the donor, acceptor, or net doping in the region may be set as the concentration of the donor, acceptor, or net doping. In the present specification, atoms/cm³ or/cm³ is used to indicate a concentration per unit volume. This unit is used for a concentration of a donor or an acceptor in a semiconductor substrate, or a chemical concentration. A notation of atoms may be omitted.

The carrier concentration measured by the SRP method may be lower than the concentration of the donor or the acceptor. In a range where a current flows when a spreading resistance is measured, the carrier mobility of the semiconductor substrate may be lower than a value in a crystalline state. The reduction in carrier mobility occurs when carriers are scattered due to disorder (disorder) of a crystal structure due to a lattice defect or the like.

The concentration of the donor or the acceptor calculated from the carrier concentration measured by the CV profiling or the SRP method may be lower than a chemical concentration of an element indicating the donor or the acceptor. As an example, in a silicon semiconductor, a donor concentration of phosphorus or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen.

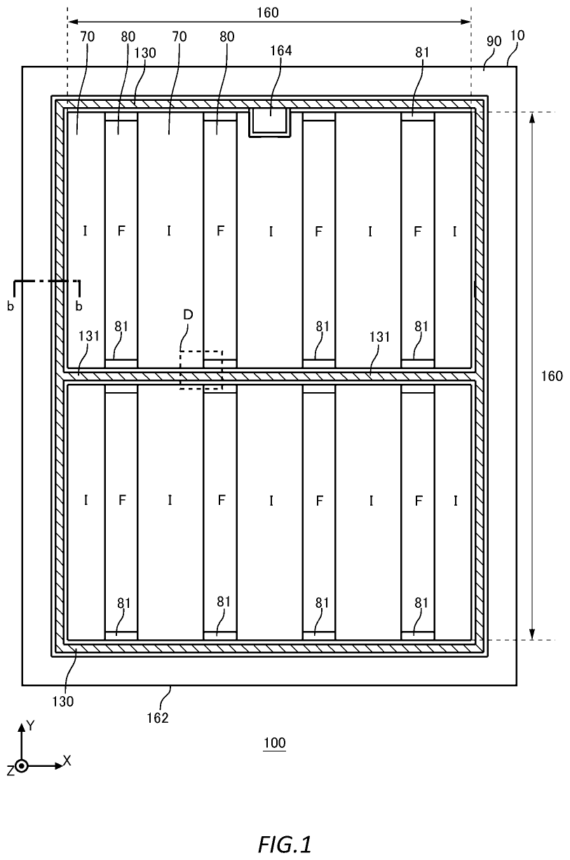

FIG. 1 illustrates a top view showing an example of a semiconductor device 100 according to one embodiment of the present invention. FIG. 1 shows a position at which each member is projected on an upper surface of a semiconductor substrate 10. FIG. 1 shows merely some members of the semiconductor device 100, and omits illustrations of some members.

The semiconductor device 100 includes the semiconductor substrate 10. The semiconductor substrate 10 is a substrate that is formed of a semiconductor material. As an example, the semiconductor substrate 10 is a silicon substrate. The semiconductor substrate 10 has an end side 162 in the top view. When merely referred to as the top view in the present specification, it means that the semiconductor substrate 10 is viewed from an upper surface side. The semiconductor substrate 10 of this example has two sets of end sides 162 opposite to each other in the top view. In FIG. 1, the X axis and the Y axis are parallel to any of the end sides 162. In addition, the Z axis is perpendicular to the upper surface of the semiconductor substrate 10.

The semiconductor substrate 10 is provided with an active portion 160. The active portion 160 is a region where a main current flows in the depth direction between the upper surface and a lower surface of the semiconductor substrate 10 when the semiconductor device 100 operates. An emitter electrode is provided above the active portion 160, but is omitted in FIG. 1. The active portion 160 may refer to a region that overlaps with the emitter electrode in the top view. Further, a region sandwiched by the active portion 160 in the top view may also be included in the active portion 160.

The active portion 160 is provided with a transistor portion 70 including a transistor element such as an IGBT (Insulated Gate Bipolar Transistor). The active portion 160 may further be provided with a diode portion 80 including a diode element such as a freewheeling diode (FWD). In the example of FIG. 1, the transistor portion 70 and the diode portion 80 are alternately arranged along a predetermined array direction (the X axis direction in this example) on the upper surface of the semiconductor substrate 10. The semiconductor device 100 of this example is a reverse-conducting IGBT (RC-IGBT).

In FIG. 1, a region where each of the transistor portions 70 is arranged is indicated by a symbol “I”, and a region where each of the diode portions 80 is arranged is indicated by a symbol F. In the present specification, a direction perpendicular to the array direction in the top view may be referred to as an extending direction (the Y axis direction in FIG. 1). Each of the transistor portions 70 and the diode portions 80 may have a longitudinal length in the extending direction. In other words, the length of each of the transistor portions 70 in the Y axis direction is larger than the width in the X axis direction. Similarly, the length of each of the diode portions 80 in the Y axis direction is larger than the width in the X axis direction. The extending direction of the transistor portion 70 and the diode portion 80, and the longitudinal direction of each trench portion described below may be the same.

Each of the diode portions 80 includes a cathode region of the N+ type in a region in contact with the lower surface of the semiconductor substrate 10. In the present specification, a region where the cathode region is provided is referred to as the diode portion 80. In other words, the diode portion 80 is a region that overlaps with the cathode region in the top view. On the lower surface of the semiconductor substrate 10, a collector region of the P+ type may be provided in a region other than the cathode region. In the present specification, the diode portion 80 may also include an extension region 81 where the diode portion 80 extends to a gate runner described below in the Y axis direction. The collector region is provided on a lower surface of the extension region 81.

The transistor portion 70 has the collector region of the P+ type in a region in contact with the lower surface of the semiconductor substrate 10. Further, in the transistor portion 70, an emitter region of the N type, a base region of the P type, and a gate structure having a gate conductive portion and a gate dielectric film are periodically arranged on the upper surface side of the semiconductor substrate 10.

The semiconductor device 100 may have one or more pads above the semiconductor substrate 10. The semiconductor device 100 of this example has a gate pad 164. The semiconductor device 100 may have a pad such as an anode pad, a cathode pad, and a current detection pad. Each pad is arranged in a region close to the end side 162. The region close to the end side 162 refers to a region between the end side 162 and the emitter electrode in the top view. When the semiconductor device 100 is mounted, each pad may be connected to an external circuit via a wiring such as a wire.

A gate potential is applied to the gate pad 164. The gate pad 164 is electrically connected to a conductive portion of a gate trench portion of the active portion 160. The semiconductor device 100 includes a gate runner that connects the gate pad 164 and the gate trench portion. In FIG. 1, the gate runner is hatched with diagonal lines.

The gate runner of this example includes an outer circumferential gate runner 130 and an active-side gate runner 131. The outer circumferential gate runner 130 is arranged between the active portion 160 and the end side 162 of the semiconductor substrate 10 in the top view. The outer circumferential gate runner 130 of this example encloses the active portion 160 in the top view. A region enclosed by the outer circumferential gate runner 130 in the top view may be the active portion 160. In addition, a well region is formed below the gate runner. The well region is a P type region having a higher concentration than the base region described below, and is formed to a position deeper than the base region from the upper surface of the semiconductor substrate 10. In the top view, the region enclosed by the well region may be the active portion 160.

The outer circumferential gate runner 130 is connected to the gate pad 164. The outer circumferential gate runner 130 is arranged above the semiconductor substrate 10. The outer circumferential gate runner 130 may be a metal wiring containing aluminum or the like.

The active-side gate runner 131 is provided in the active portion 160. Providing the active-side gate runner 131 in the active portion 160 can reduce a variation in wiring length from the gate pad 164 for each region of the semiconductor substrate 10.

The outer circumferential gate runner 130 and the active-side gate runner 131 are connected to the gate trench portion of the active portion 160. The outer circumferential gate runner 130 and the active-side gate runner 131 are arranged above the semiconductor substrate 10. The outer circumferential gate runner 130 and the active-side gate runner 131 may be a wiring formed of a semiconductor such as polysilicon doped with an impurity.

The active-side gate runner 131 may be connected to the outer circumferential gate runner 130. The active-side gate runner 131 of this example is provided extending in the X axis direction so as to cross the active portion 160 from one outer circumferential gate runner 130 to the other outer circumferential gate runner 130 sandwiching the active portion 160, substantially at the center of the Y axis direction. When the active portion 160 is divided by the active-side gate runner 131, the transistor portion 70 and the diode portion 80 may be alternately arranged in the X axis direction in each of the divided regions.

The semiconductor device 100 may include a temperature sensing portion (not shown) that is a PN junction diode formed of polysilicon or the like, and a current detection portion (not shown) that simulates an operation of the transistor portion provided in the active portion 160.

The semiconductor device 100 of this example includes an edge termination structure portion 90 between the active portion 160 and the end side 162 in the top view. The edge termination structure portion 90 of this example is arranged between the outer circumferential gate runner 130 and the end side 162. The edge termination structure portion 90 relaxes an electric field strength on the upper surface side of the semiconductor substrate 10. The edge termination structure portion 90 may include at least one of a guard ring, a field plate, or a RESURF annularly provided to enclose the active portion 160.

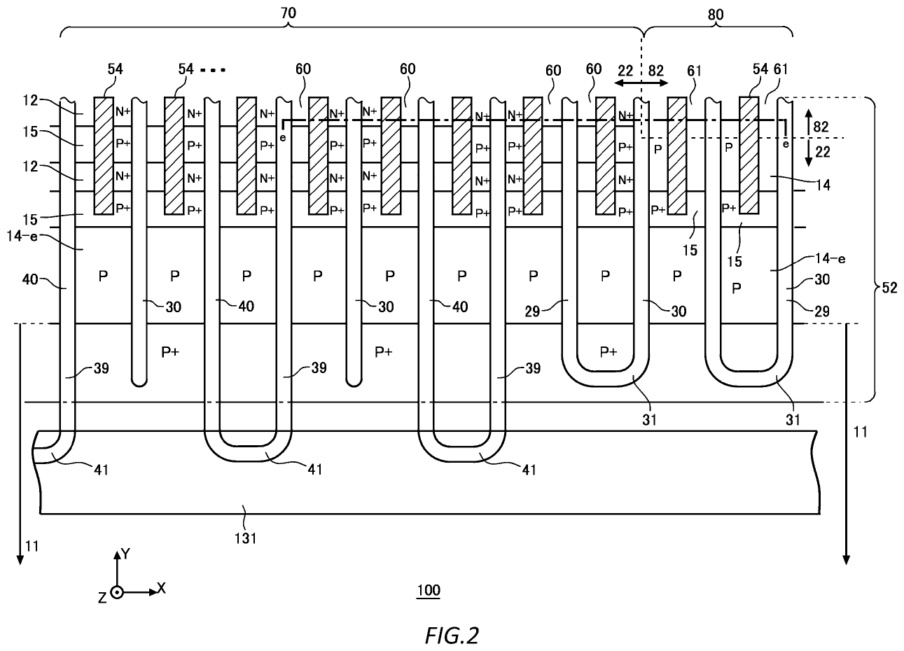

FIG. 2 illustrates an enlarged view of a region D in FIG. 1. The region D is a region including the transistor portion 70, the diode portion 80, and the active-side gate runner 131. The semiconductor device 100 of this example includes a gate trench portion 40, a dummy trench portion 30, a well region 11, an emitter region 12, a base region 14, and a contact region 15, which are provided inside the semiconductor substrate 10 on the upper surface side. The gate trench portion 40 and the dummy trench portion 30 each are an example of the trench portion. In addition, the semiconductor device 100 of this example includes an emitter electrode 52 and the active-side gate runner 131 which are provided above the upper surface of the semiconductor substrate 10. The emitter electrode 52 and the active-side gate runner 131 are provided separate from each other.

An interlayer dielectric film is provided between the emitter electrode 52 and the active-side gate runner 131, and the upper surface of the semiconductor substrate 10, but the interlayer dielectric film is omitted in FIG. 2. In the interlayer dielectric film of this example, a contact hole 54 is provided passing through the interlayer dielectric film. In FIG. 2, each contact hole 54 is hatched with the diagonal lines.

The emitter electrode 52 is provided above the gate trench portion 40, the dummy trench portion 30, the well region 11, the emitter region 12, the base region 14, and the contact region 15. The emitter electrode 52 is in contact with the emitter region 12, the contact region 15, and the base region 14 on the upper surface of the semiconductor substrate 10, through the contact hole 54. Further, the emitter electrode 52 is connected to a dummy conductive portion in the dummy trench portion 30 through the contact hole provided in the interlayer dielectric film. The emitter electrode 52 may be connected to the dummy conductive portion of the dummy trench portion 30 at an edge of the dummy trench portion 30 in the Y axis direction. The dummy conductive portion of the dummy trench portion 30 does not need to be connected to the emitter electrode 52 and the gate conductive portion, and may be controlled to be set at a potential different from the potential of the emitter electrode 52 and the potential of the gate conductive portion.

The active-side gate runner 131 is connected to the gate trench portion 40 through the contact hole provided in the interlayer dielectric film. The active-side gate runner 131 may be connected to a gate conductive portion of the gate trench portion 40 in an edge portion 41 of the gate trench portion 40 in the Y axis direction. The active-side gate runner 131 is not connected to the dummy conductive portion in the dummy trench portion 30.

The emitter electrode 52 is formed of a material including metal. FIG. 2 shows a range where the emitter electrode 52 is provided. For example, at least a part of a region of the emitter electrode 52 is formed of aluminum or an aluminum-silicon alloy, for example, a metal alloy such as AlSi and AlSiCu. The emitter electrode 52 may have a barrier metal formed of titanium, a titanium compound, or the like below a region formed of aluminum or the like. Further, a plug, which is formed by embedding tungsten or the like so as to be in contact with the barrier metal and aluminum or the like, may be included in the contact hole.

The well region 11 is provided so as to overlap with the active-side gate runner 131. The well region 11 is provided so as to extend with a predetermined width also in a range not overlapping with the active-side gate runner 131. The well region 11 of this example is provided away from an end of the contact hole 54 in the Y axis direction toward the active-side gate runner 131 side. The well region 11 is a region of a second conductivity type in which the doping concentration is higher than that of the base region 14. The base region 14 of this example is a P type, and the well region 11 is a P+ type.

Each of the transistor portion 70 and the diode portion 80 includes a plurality of trench portions arranged in the array direction. In the transistor portion 70 of this example, one or more gate trench portions 40 and one or more dummy trench portions 30 are alternately provided along the array direction. In the diode portion 80 of this example, the plurality of dummy trench portions 30 are provided along the array direction. In the diode portion 80 of this example, the gate trench portion 40 is not provided.

The gate trench portion 40 of this example may have two linear portions 39 extending along the extending direction perpendicular to the array direction (portions of a trench that are linear along the extending direction), and the edge portion 41 connecting the two linear portions 39. The extending direction in FIG. 2 is the Y axis direction.

At least a part of the edge portion 41 is preferably provided in a curved shape in a top view. By connecting end portions of the two linear portions 39 in the Y axis direction by the edge portion 41, it is possible to relax an electric field strength at the end portions of the linear portions 39.

In the transistor portion 70, the dummy trench portions 30 are provided between the respective linear portions 39 of the gate trench portions 40. Between the respective linear portions 39, one dummy trench portion 30 may be provided, or a plurality of dummy trench portions 30 may be provided. The dummy trench portion 30 may have a linear shape extending in the extending direction, or may have linear portions 29 and an edge portion 31 similar to the gate trench portion 40. The semiconductor device 100 shown in FIG. 2 includes both of the linear dummy trench portion 30 having no edge portion 31, and the dummy trench portion 30 having the edge portion 31.

A diffusion depth of the well region 11 may be deeper than the depth of the gate trench portion 40 and the dummy trench portion 30. The end portions of the gate trench portion 40 and the dummy trench portion 30 in the Y axis direction are provided in the well region 11 in a top view. In other words, the bottom of each trench portion in the depth direction is covered with the well region 11 at the end portion of each trench portion in the Y axis direction. With this configuration, the electric field strength at the bottom of each trench portion can be relaxed.

A mesa portion is provided between the respective trench portions in the array direction. The mesa portion refers to a region sandwiched between the trench portions inside the semiconductor substrate 10. As an example, an upper end of the mesa portion is the upper surface of the semiconductor substrate 10. The depth position of the lower end of the mesa portion is the same as the depth position of the lower end of the trench portion. The mesa portion of this example is provided extending in the extending direction (the Y axis direction) along the trench, on the upper surface of the semiconductor substrate 10. In this example, a mesa portion 60 is provided in the transistor portion 70, and a mesa portion 61 is provided in the diode portion 80. In the case of simply mentioning “mesa portion” in the present specification, the portion refers to each of the mesa portion 60 and the mesa portion 61.

Each mesa portion is provided with the base region 14. Of the base regions 14 exposed on the upper surface of the semiconductor substrate 10 in the mesa portion, a region arranged closest to the active-side gate runner 131 is assumed to be a base region 14-e. While FIG. 2 shows the base region 14-e arranged at one end portion of each mesa portion in the extending direction, the base region 14-e is also arranged at the other end portion of each mesa portion. In each mesa portion, at least one of the emitter region 12 of the first conductivity type or the contact region 15 of the second conductivity type may be provided in a region sandwiched between the base regions 14-e in a top view. The emitter region 12 of this example is an N+ type, and the contact region 15 is a P+ type. The emitter region 12 and the contact region 15 may be provided between the base region 14 and the upper surface of the semiconductor substrate 10 in the depth direction.

The mesa portion 60 of the transistor portion 70 has the emitter region 12 in contact with the upper surface (that is, exposed on the upper surface) of the semiconductor substrate 10. The emitter region 12 is provided in contact with the gate trench portion 40. The mesa portion 60 in contact with the gate trench portion 40 may be provided with the contact region 15 exposed on the upper surface of the semiconductor substrate 10.

Each of the contact region 15 and the emitter region 12 in the mesa portion 60 is provided from one trench portion to the other trench portion in the X axis direction. As an example, the contact region 15 and the emitter region 12 of the mesa portion 60 are alternately arranged along the extending direction of the trench portion (the Y axis direction).

In another example, the contact region 15 and the emitter region 12 of the mesa portion 60 may be provided in a stripe pattern along the extending direction of the trench portion (the Y axis direction). For example, the emitter region 12 is provided in a region in contact with the trench portion, and the contact region 15 is provided in a region sandwiched between the emitter regions 12.

The mesa portion 61 of the diode portion 80 is not provided with the emitter region 12. The base region 14 and the contact region 15 may be provided on an upper surface of the mesa portion 61. In the region sandwiched between the base regions 14-e on the upper surface of the mesa portion 61, the contact region 15 may be provided in contact with each base region 14-e. The base region 14 may be provided in a region sandwiched between the contact regions 15 on the upper surface of the mesa portion 61. The base region 14 may be arranged in the entire region sandwiched between the contact regions 15.

The contact hole 54 is provided above each mesa portion. The contact hole 54 is arranged in the region sandwiched between the base regions 14-e. The contact hole 54 of this example is provided above each region of the contact region 15, the base region 14, and the emitter region 12. The contact hole 54 is not provided in regions corresponding to the base region 14-e and the well region 11. The contact hole 54 may be arranged at the center of the mesa portion 60 in the array direction (the X axis direction).

In the diode portion 80, an N+ type cathode region 82 is provided in a region in direct contact with the lower surface of the semiconductor substrate 10. On the lower surface of the semiconductor substrate 10, a P+ type active collector region 22 may be provided in a region where the cathode region 82 is not provided. The cathode region 82 and the active collector region 22 are provided between the lower surface 23 of the semiconductor substrate 10 and a buffer region 20. In FIG. 2, a boundary between the cathode region 82 and the active collector region 22 is indicated by a dotted line.

The cathode region 82 is arranged apart from the well region 11 in the Y axis direction. With this configuration, a distance between the P type region (the well region 11) which has a relatively high doping concentration and is formed up to a deep position and the cathode region 82 is ensured, so that the breakdown voltage can be improved. The end portion of the cathode region 82 of this example in the Y axis direction is arranged farther away from the well region 11 than the end portion of the contact hole 54 in the Y axis direction. In another example, the end portion of the cathode region 82 in the Y axis direction may be arranged between the well region 11 and the contact hole 54.

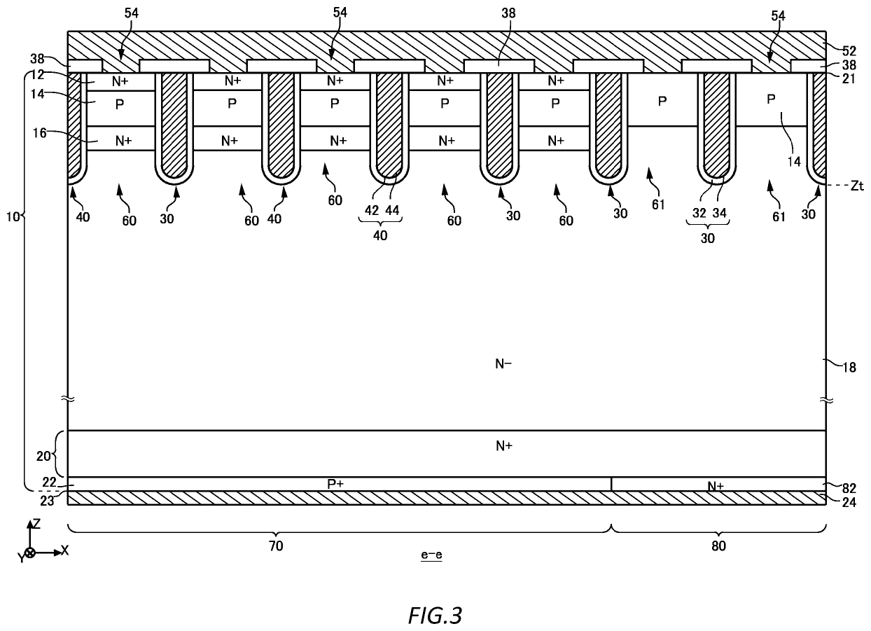

FIG. 3 illustrates a view showing an example of a cross section e-e in FIG. 2. The cross section e-e is an XZ plane passing through the emitter region 12 and the cathode region 82. The semiconductor device 100 of this example includes the semiconductor substrate 10, the interlayer dielectric film 38, the emitter electrode 52, and the collector electrode 24 in the cross section.

The interlayer dielectric film 38 is provided on the upper surface of the semiconductor substrate 10. The interlayer dielectric film 38 is a film including at least one layer of a dielectric film such as silicate glass to which an impurity such as boron or phosphorus is added, a thermal oxide film, and other dielectric films. The interlayer dielectric film 38 is provided with the contact hole 54 described in FIG. 2.

The emitter electrode 52 is provided above the interlayer dielectric film 38. The emitter electrode 52 is in contact with the upper surface 21 of the semiconductor substrate 10 through the contact hole 54 of the interlayer dielectric film 38. The collector electrode 24 is provided on the lower surface 23 of the semiconductor substrate 10. The emitter electrode 52 and the collector electrode 24 are formed of a metal material such as aluminum. In the present specification, the direction in which the emitter electrode 52 is connected to the collector electrode 24 (the Z axis direction) is referred to as the depth direction.

The semiconductor substrate 10 includes an N type or N-type drift region 18. The drift region 18 is provided in each of the transistor portion 70 and the diode portion 80.

In the mesa portion 60 of the transistor portion 70, an N+ type emitter region 12 and a P type base region 14 are provided in order from an upper surface 21 side of the semiconductor substrate 10. The drift region 18 is provided below the base region 14. The mesa portion 60 may be provided with an N+ type accumulation region 16. The accumulation region 16 is arranged between the base region 14 and the drift region 18. The accumulation region 16 is an N+ type region having a higher doping concentration than the drift region 18. By providing the accumulation region 16 having a high concentration between the drift region 18 and the base region 14, it is possible to improve a carrier injection enhancement effect (IE effect) and reduce an on-voltage. The accumulation region 16 may be provided to cover an entire lower surface of the base region 14 in each mesa portion 60. The accumulation region 16 may also be provided in each mesa portion 61 of the diode portion 80, or does not need to be provided.

The emitter region 12 is exposed on the upper surface 21 of the semiconductor substrate 10 and is provided in contact with gate trench portion 40. The emitter region 12 may be in contact with the trench portions on both sides of the mesa portion 60. The emitter region 12 has a higher doping concentration than the drift region 18.

The base region 14 is provided below the emitter region 12. The base region 14 of this example is provided in contact with the emitter region 12. The base region 14 may be in contact with the trench portions on both sides of the mesa portion 60.

The mesa portion 61 of the diode portion 80 is provided with the P type base region 14 in contact with the upper surface 21 of the semiconductor substrate 10. The drift region 18 is provided below the base region 14. The base region 14 of the diode portion 80 may be referred to as an anode region.

In each of the transistor portion 70 and the diode portion 80, an N+ type buffer region 20 may be provided below the drift region 18. The doping concentration of the buffer region 20 is higher than the doping concentration of the drift region 18. The buffer region 20 may have a concentration peak having a higher doping concentration than the drift region 18. The doping concentration of the concentration peak refers to a doping concentration at a local maximum of the concentration peak. Further, as the doping concentration of the drift region 18, an average value of doping concentrations in a region where the doping concentration distribution is substantially flat may be used.

The buffer region 20 may have two or more concentration peaks in the depth direction (Z axis direction) of the semiconductor substrate 10. The concentration peak of the buffer region 20 may be provided at the same depth position as, for example, a chemical concentration peak of hydrogen (proton) or phosphorus. The buffer region 20 may function as a field stop layer which prevents a depletion layer expanding from a lower end of the base region 14 from reaching the P+ type active collector region 22 and the N+ type cathode region 82.

In the transistor portion 70, the P+ type active collector region 22 is provided between the lower surface 23 of the semiconductor substrate 10 and the drift region 18. The active collector region 22 of this example is provided in contact with the buffer region 20 and the lower surface 23 of the semiconductor substrate 10. A maximum value of an acceptor concentration in the active collector region 22 is higher than a maximum value of an acceptor concentration in the base region 14. The active collector region 22 may contain an acceptor which is the same as or different from an acceptor of the base region 14. The acceptor of the active collector region 22 is, for example, boron.

Below the buffer region 20 in the diode portion 80, the cathode region 82 of the N+ type is provided. A donor concentration of the cathode region 82 is higher than a donor concentration of the drift region 18. A donor of the cathode region 82 is, for example, hydrogen or phosphorus. Note that an element serving as a donor and an acceptor in each region is not limited to the above described example. The active collector region 22 and the cathode region 82 are exposed on the lower surface 23 of the semiconductor substrate 10 and are connected to the collector electrode 24. The collector electrode 24 may be in contact with the entire lower surface 23 of the semiconductor substrate 10. The emitter electrode 52 and the collector electrode 24 are formed of a metal material such as aluminum.

One or more gate trench portions 40 and one or more dummy trench portions 30 are provided on the upper surface 21 side of the semiconductor substrate 10. Each trench portion passes through the base region 14 from the upper surface 21 of the semiconductor substrate 10, and is provided to below the base region 14. In a region where at least any of the emitter region 12, the contact region 15, or the accumulation region is provided, each trench portion also passes through the doping regions of these. The configuration of the trench portion passing through the doping region is not limited to that manufactured in the order of forming the doping region and then forming the trench portion. The configuration of the trench portion passing through the doping region also includes a configuration of the doping region being formed between the trench portions after forming the trench portion.

As described above, the transistor portion 70 is provided with the gate trench portion 40 and the dummy trench portion 30. In the diode portion 80, the dummy trench portion 30 is provided, and the gate trench portion 40 is not provided. In this example, a boundary between the diode portion 80 and the transistor portion 70 in the X axis direction is the boundary between the cathode region 82 and the active collector region 22.

The gate trench portion 40 includes a gate trench, a gate dielectric film 42, and a gate conductive portion 44 provided on the upper surface 21 of the semiconductor substrate 10. The gate dielectric film 42 is provided to cover the inner wall of the gate trench. The gate dielectric film 42 may be formed by oxidizing or nitriding a semiconductor on the inner wall of the gate trench. The gate conductive portion 44 is provided on an inner side of the gate dielectric film 42 inside the gate trench. That is, the gate dielectric film 42 insulates the gate conductive portion 44 from the semiconductor substrate 10. The gate conductive portion 44 is formed of a conductive material such as polysilicon.

The gate conductive portion 44 may be provided to be longer than the base region 14 in the depth direction. The gate trench portion 40 in the cross section is covered by the interlayer dielectric film 38 on the upper surface 21 of the semiconductor substrate 10. The gate conductive portion 44 is electrically connected to the gate runner. When a predetermined gate voltage is applied to the gate conductive portion 44, a channel is formed by an electron inversion layer in a surface layer of the base region 14 at a boundary in contact with the gate trench portion 40.

The dummy trench portions 30 may have the same structure as the gate trench portions 40 in the cross section. The dummy trench portion 30 includes a dummy trench, a dummy dielectric film 32, and a dummy conductive portion 34 provided on the upper surface 21 of the semiconductor substrate 10. The dummy conductive portion 34 is electrically connected to the emitter electrode 52. The dummy dielectric film 32 is provided to cover an inner wall of the dummy trench. The dummy conductive portion 34 is provided inside the dummy trench, and is provided on an inner side of the dummy dielectric film 32. The dummy dielectric film 32 insulates the dummy conductive portion 34 from the semiconductor substrate 10. The dummy conductive portion 34 may be formed of the same material as the gate conductive portion 44. For example, the dummy conductive portion 34 is formed of a conductive material such as polysilicon. The dummy conductive portion 34 may have the same length as the gate conductive portion 44 in the depth direction.

The gate trench portion 40 and the dummy trench portion 30 of this example are covered by the interlayer dielectric film 38 on the upper surface 21 of the semiconductor substrate 10. Note that the bottoms of the dummy trench portion 30 and the gate trench portion 40 may be formed in a curved-surface shape (a curved shape in the cross section) convexly downward. In the present specification, the depth position of the lower end of the gate trench portion 40 is defined as Zt.

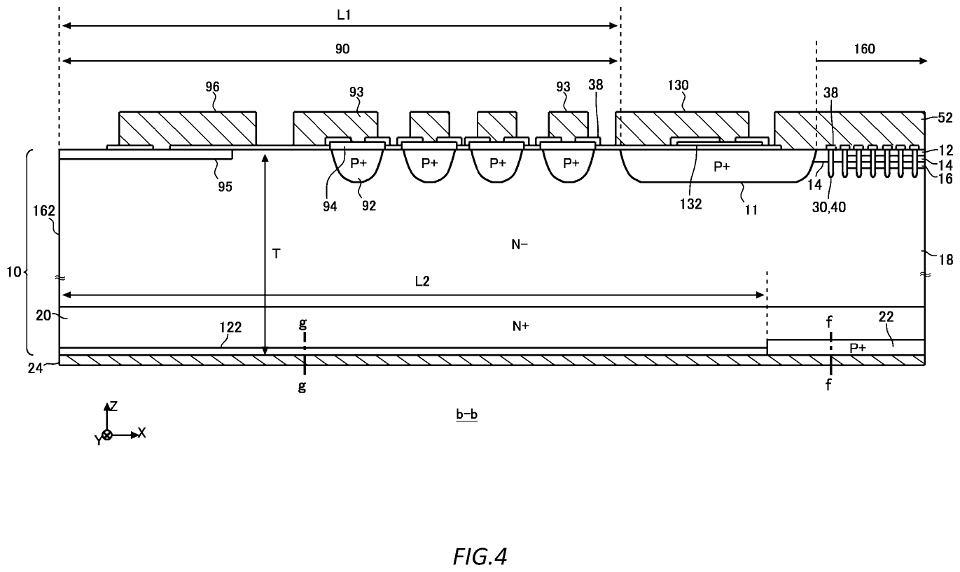

FIG. 4 illustrates a view showing an example of a cross section b-b in FIG. 1. The cross section b-b is an XZ plane that passes through the edge termination structure portion 90 and a part of the active portion 160 (the transistor portion 70). The edge termination structure portion 90 is arranged between the emitter electrode 52 and the end side 162 of the semiconductor substrate 10 in a top view. The emitter electrode 52 is an example of an upper surface electrode arranged above the upper surface 21 of the semiconductor substrate 10.

The edge termination structure portion 90 may include one or more guard rings 92. The edge termination structure portion 90 may include one or more field plates 93. The guard rings 92 are each a P+ type region provided in contact with the upper surface 21 of the semiconductor substrate 10. The guard rings 92 enclose the active portion 160. The field plates 93 are each a metal member arranged above the upper surface 21 of the semiconductor substrate 10. The interlayer dielectric film 38 may be provided between the field plates 93 and the semiconductor substrate 10. The field plates 93 and the guard rings 92 may or may not be electrically connected. In this example, the field plates 93 and the guard rings 92 are connected via a polysilicon wiring 94 provided on the upper surface of the semiconductor substrate 10.

On an outer side of the guard rings 92 and the field plates 93, a channel stopper 95 and an electrode 96 may be provided. The channel stopper 95 prevents a depletion layer extending from the active portion 160 from reaching the end side 162 of the semiconductor substrate 10. The channel stopper 95 is a P type or N type region having a higher concentration than the drift region 18. The electrode 96 is connected to the channel stopper 95. The same potential as the collector electrode 24 may be applied to the electrode 96.

The outer circumferential gate runner 130 is provided between the active portion 160 and the edge termination structure portion 90. A polysilicon gate runner 132 may be provided between the outer circumferential gate runner 130 and the semiconductor substrate 10. The well region 11 is provided below the outer circumferential gate runner 130 and the gate runner 132. The well region 11 may be connected to the emitter electrode 52. The well region 11 may be in contact with the base region 14.

Of the end portions of the well region 11 on the upper surface 21 of the semiconductor substrate 10, the end portion opposing the end side 162 of the semiconductor substrate 10 may be an end portion of the edge termination structure portion 90. In another example, of the end portions of the outer circumferential gate runner 130 in the top view, the end portion opposing the end side 162 of the semiconductor substrate 10 may be the end portion of the edge termination structure portion 90.

Of the end portions of the well region 11 on the upper surface 21 of the semiconductor substrate 10, the end portion on an opposite side of the end portion opposing the end side 162 of the semiconductor substrate 10 may be an end portion of the active portion 160. In another example, the end portion of the emitter electrode 52 in the top view may be the end portion of the active portion 160. The entire active portion 160 may be arranged below the emitter electrode 52. Alternatively, of the end portions of the outer circumferential gate runner 130 in the top view, the end portion on an opposite side of the end portion opposing the end side 162 of the semiconductor substrate 10 may be the end portion of the active portion 160.

The edge termination structure portion 90 includes a P+ type edge collector region 122 arranged between the lower surface 23 and the drift region 18 in the semiconductor substrate 10. The edge collector region 122 of this example is provided in contact with the buffer region 20 and the lower surface 23 of the semiconductor substrate 10. The edge collector region 122 may be provided across the entire edge termination structure portion 90 in the top view, or may be provided in a part of the edge termination structure portion 90 in the top view.

As in a surge voltage during turn-off of the semiconductor device 100, or the like, a large voltage may be applied to the semiconductor substrate 10. If avalanche breakdown occurs in the edge termination structure portion 90 first before the active portion 160 when a large voltage is applied to the semiconductor substrate 10, a clamp withstand capability (a withstand capability when an overvoltage is applied) of the semiconductor device 100 becomes small.

For example, if avalanche breakdown occurs at any position in the semiconductor substrate 10, the avalanche breakdown may also sequentially occur in nearby regions. When avalanche breakdown occurs in the active portion 160, since the active portion 160 has a relatively large area, the avalanche breakdown sequentially occurs in a relatively large region. Thus, if avalanche breakdown occurs in the active portion 160 first, avalanche currents that flow due to the avalanche breakdown can be distributed in the large active portion 160, with the result that the withstand capability of the semiconductor device 100 becomes relatively large. On the other hand, since the edge termination structure portion 90 has a low breakdown voltage, if avalanche breakdown occurs in the edge termination structure portion 90 first, it is difficult for a region where the avalanche breakdown occurs to spread in the active portion 160 having a high breakdown voltage. Thus, the avalanche currents are locally converged at a boundary portion between the edge termination structure portion 90 and the active portion 160 and become a positive feedback so as to cause a destructive failure of the semiconductor device 100.

In the semiconductor device 100 of this example, the edge termination structure portion 90 is provided with the edge collector region 122 different from the active collector region 22 so that it becomes easy to cause avalanche breakdown in the active portion 160 and relatively suppress occurrence of avalanche breakdown in the edge termination structure portion 90. With this configuration, the withstand capability of the semiconductor device 100 is improved.

An integrated value obtained by integrating the carrier concentration of the active collector region 22 in the depth direction of the semiconductor substrate 10 (the Z axis direction) is represented by I1. Further, an integrated value obtained by integrating the carrier concentration of the edge collector region 122 in the depth direction of the semiconductor substrate 10 (the Z axis direction) is represented by I2. The integrated value I1 is larger than the integrated value I2. Accordingly, the hole implantation efficiency from the active collector region 22 can be made to be higher than the hole implantation efficiency from the edge collector region 122. Accordingly, it becomes easy to cause avalanche breakdown in the active portion 160 during turn-off of the semiconductor device 100, or the like.

The implantation efficiency is as follows. For example, a current density of holes is represented by Jₚ, and a current density of electrons is represented by Jₙ. The implantation efficiency of each of the collector regions is a ratio of a current density of minority carriers to a total current density. In this example, since the conductivity type of the drift region 18 is the N type and the conductivity type of the collector regions is the P type, the minority carriers of the drift region 18 are holes. In this case, the implantation efficiency in the collector regions can be defined using Expression (1).

Jₚ/(Jₚ+Jₙ) Expression (1)

In general, the implantation efficiency refers to efficiency in the electrode such as the collector electrode 24 or the emitter electrode 52, but in this example, the implantation efficiency refers to implantation efficiency in each of the collector regions since minority carriers are implanted from the collector regions. As the integrated value of the carrier concentration of the collector region becomes larger, more holes are implanted from the collector region. Thus, by increasing the integrated value of the carrier concentration of the collector region, the hole implantation efficiency can be raised.

When a thickness T of the semiconductor substrate 10 in the depth direction is small and a width L1 of the edge termination structure portion 90 in the top view is small, avalanche breakdown is apt to occur in the edge termination structure portion 90. The width L1 of the edge termination structure portion 90 is, for example, a distance from the end side 162 of the semiconductor substrate 10 to the well region 11. The width L1 may alternatively be a distance from the end side 162 to the outer circumferential gate runner 130. In this example, a case where the thickness T is ⅕ or more of the width L1 may be assumed. Even in such a case, the occurrence of avalanche breakdown in the edge termination structure portion 90 can be suppressed by raising the hole implantation efficiency of the active collector region 22. The thickness T may be smaller than 1/7 or 1/10 of the width L1.

The region enclosed by the well regions 11 in the top view may be the active portion 160. The emitter electrode 52 is arranged above the region. An entire region overlapping with the emitter electrode 52 in the top view may be the active portion 160. An entire region enclosed by connecting outermost end portions of a portion where the emitter electrode 52 is in contact with the upper surface of the semiconductor substrate 10 may be the active portion 160.

A width of the edge collector region 122 in the top view is represented by L2. The width L2 is a distance from the end side 162 of the semiconductor substrate 10 to a boundary position between the edge collector region 122 and the active collector region 22. The width L2 of the edge collector region 122 may be the same as the width L1 of the edge termination structure portion 90, or may be larger than the width L1. In the example of FIG. 4, the boundary position between the edge collector region 122 and the active collector region 22 is arranged between the edge termination structure portion 90 and the active portion 160. The boundary position may be arranged below the well region 11. The edge collector region 122 may be extended to the active portion 160 so that the boundary position between the edge collector region 122 and the active collector region 22 is arranged closer to the active portion 160 than the end portion of the well region 11 on the inner circumferential side.

The depth of the edge collector region 122 in the Z axis direction may be the same as the depth of the active collector region 22 in the Z axis direction, may be deeper toward the upper surface 21 side than the depth of the active collector region 22 in the Z axis direction, or may be shallower toward the lower surface 23 side. In this example, the depth of the edge collector region 122 in the Z axis direction is shallower toward the lower surface 23 side than the active collector region 22.

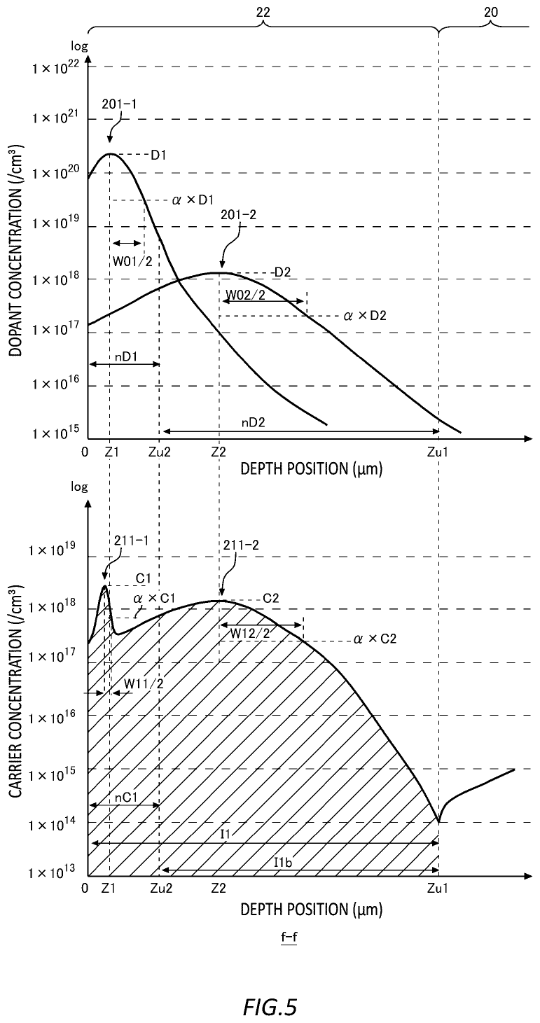

FIG. 5 illustrates a view showing a distribution example of a dopant concentration and a carrier concentration on a line f-f in FIG. 4 in the depth direction. The line f-f is a line that passes through the active collector region 22 and is parallel to the Z axis.

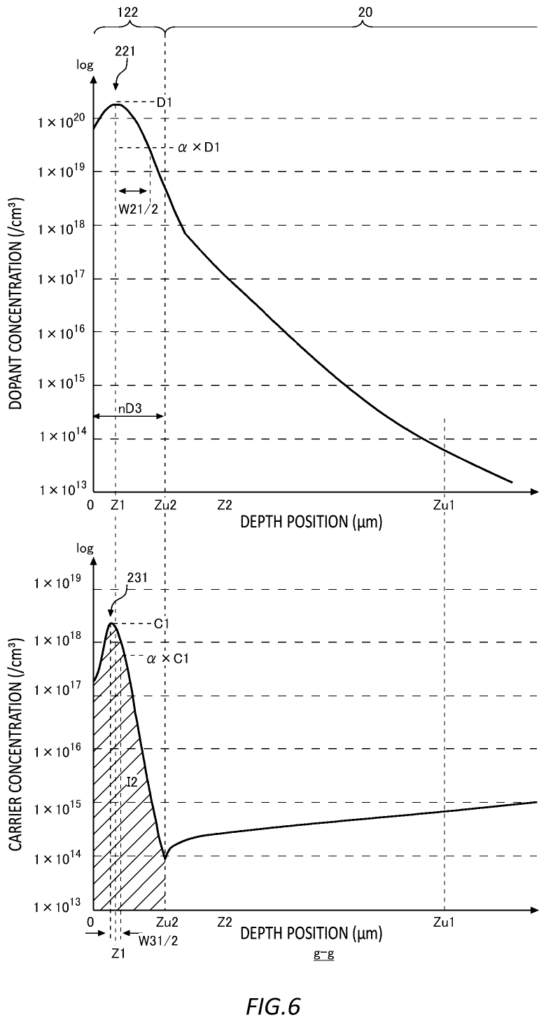

FIG. 6 illustrates a view showing a distribution example of the dopant concentration and the carrier concentration on a line g-g in FIG. 4 in the depth direction. The line g-g is a line that passes through the edge collector region 122 and is parallel to the Z axis.

The horizontal axis in each of FIGS. 5 and 6 represents a position in the depth direction using the lower surface 23 of the semiconductor substrate 10 as a reference. In other words, the horizontal axis represents a distance from the lower surface 23 in the Z axis direction. Moreover, the dopant concentration in each of FIGS. 5 and 6 indicates a chemical concentration of a dopant that has been measured by the SIMS method or the like. The dopant in FIGS. 5 and 6 is boron as an example, but is not limited thereto. Note that in FIGS. 5 and 6 of this example, only the chemical concentration of boron is described as the dopant concentration. The carrier concentration in FIGS. 5 and 6 may be measured by, for example, the SRP method.

As shown in FIG. 5, an upper end position of the active collector region 22 is represented by Zu1. The upper end position Zu1 is a position of a boundary between the active collector region 22 and the N type region (the buffer region 20 in the example of FIG. 4). The upper end position Zu1 of this example indicates a position at which the carrier concentration becomes 1×10¹⁴/cm³, but is not limited thereto. Since a PN junction is formed at the upper end position Zu1, the carrier concentration shows a valley shape. The integrated value I1 of the active collector region 22 may be an integrated value obtained by integrating the carrier concentration from the depth position of the lower surface 23 of the semiconductor substrate 10 (0 μm) to the depth position Zu1 in the depth direction of the semiconductor substrate 10 (the Z axis direction).

As shown in FIG. 6, an upper end position of the edge collector region 122 is represented by Zu2. The upper end position Zu2 is a position of a boundary between the edge collector region 122 and the N type region (the buffer region 20 in the example of FIG. 4). The upper end position Zu2 of this example indicates a position at which the carrier concentration becomes 1×10¹⁴/cm³, but is not limited thereto. Since a PN junction is formed at the upper end position Zu2, the carrier concentration shows a valley shape. The integrated value I2 of the edge collector region 122 may be an integrated value obtained by integrating the carrier concentration from the depth position of the lower surface 23 of the semiconductor substrate 10 (0 μm) to the depth position Zu2 in the depth direction of the semiconductor substrate 10 (the Z axis direction).

As the integrated concentration of the carrier concentration of the active collector region 22, an integrated value I1b obtained by integrating the carrier concentration from the depth position Zu2 to the depth position Zu1 in the depth direction of the semiconductor substrate 10 (the Z axis direction) may be used. The integrated value I1b may be larger than the integrated value I2.

As described above, the integrated value I1 of the carrier concentration of the active collector region 22 in the depth direction is larger than the integrated value I2 of the carrier concentration of the edge collector region 122 in the depth direction. The integrated value I1 is a value obtained by integrating the carrier concentration of the active collector region 22 in the depth range from 0 μm to Zu1. The integrated value I2 is a value obtained by integrating the carrier concentration of the edge collector region 122 in the depth range from 0 μm to Zu2. The integration ranges in the carrier concentration distributions of FIGS. 5 and 6 are hatched with diagonal lines.

As shown in FIGS. 5 and 6, the upper end position Zu1 of the active collector region 22 and the upper end position Zu2 of the edge collector region 122 differ. In the examples of FIGS. 4 to 6, the upper end position Zu1 of the active collector region 22 is farther away from the lower surface 23 of the semiconductor substrate 10 than the upper end position Zu2 of the edge collector region 122. Accordingly, the integrated value I1 of the carrier concentration in the active collector region 22 can be easily made to be larger than the integrated value I2 of the carrier concentration in the edge collector region 122. The distance from the lower surface 23 to the upper end position Zu1 may be equal to or larger than the distance from the lower surface 23 to the upper end position Zu2, or may be 2 times or more, 3 times or more, or 5 times or more of the distance from the lower surface 23 to the upper end position Zu2.

In another example, the upper end position Zu2 of the edge collector region 122 may be farther away from the lower surface 23 of the semiconductor substrate 10 than the upper end position Zu1 of the active collector region 22. Also in this case, by increasing the average value of the carrier concentrations in the active collector region 22, the integrated value I1 of the carrier concentration of the active collector region 22 can be made to be larger than the integrated value I2 of the carrier concentration of the edge collector region 122.

As shown in FIG. 5, the active collector region 22 has one or more active peaks 201 that are each a chemical concentration peak of a P type dopant in the depth direction. The active collector region 22 may alternatively have two or more active peaks 201. In the example of FIG. 5, the active collector region 22 has an active peak 201-1 and an active peak 201-2. The active peak 201-2 is arranged farther away from the lower surface 23 than the active peak 201-1.

As shown in FIG. 5, the active collector region 22 has one or more carrier concentration peaks 211 in the depth direction. The active collector region 22 may alternatively have two or more carrier concentration peaks 211. In the example of FIG. 5, the active collector region 22 has a carrier concentration peak 211-1 and a carrier concentration peak 211-2. In the present specification, the carrier concentration peak 211-1 may be referred to as a first carrier concentration peak, and the carrier concentration peak 211-2 may be referred to as a second carrier concentration peak. The carrier concentration peak 211-2 is arranged farther away from the lower surface 23 than the carrier concentration peak 211-1.

A position of a local maximum of each peak is a peak position. In the example of FIG. 5, a depth position of the active peak 201-1 is represented by Z1, and a depth position of the active peak 201-2 is represented by Z2. The carrier concentration peak 211 may be arranged at the same depth position as the active peak 201. In the example of FIG. 5, the carrier concentration peak 211-1 and the carrier concentration peak 211-2 are respectively arranged at the depth positions Z1 and Z2. Note that the position of the carrier concentration peak 211 may contain an error with respect to the position of the corresponding active peak 201. In the example of FIG. 5, the depth position of the carrier concentration peak 211-2 is the same as the depth position of the active peak 201-2. In the example of FIG. 5, the depth position of the carrier concentration peak 211-1 is arranged between the depth position Z1 of the active peak 201-1 and the lower surface 23. When the concentration of the corresponding active peak 201 is high, many lattice defects are formed in the vicinity of the local maximum of the active peak 201. When lattice defects are not sufficiently recovered due to annealing or the like, many lattice defects may remain in the vicinity of the local maximum of the active peak 201 to thus lower the carrier concentration in the vicinity of the local maximum of the active peak 201. In the example of FIG. 5, the carrier concentration peak 211-1 is arranged at a position slightly deviated from the depth position of the active peak 201-1 toward the lower surface 23 side. A distance between the depth position of the corresponding carrier concentration peak 211 and the depth position of the active peak 201 may be 0.05 μm or less, 0.03 μm or less, or 0.02 μm or less. A value (ratio) obtained by dividing the depth position of the corresponding carrier concentration peak 211 (the distance from the lower surface 23) by the depth position of the active peak 201 (the distance from the lower surface 23) may be 200% or less, 150% or less, 100% or less, 50% or less, or 20% or less.

The entire active collector region 22 in the top view may have the concentration distribution shown in FIG. 5. In another example, a part of the active collector region 22 in the top view may have the carrier concentration peak 211-1 and the carrier concentration peak 211-2. In another partial region of the active collector region 22 in the top view, the carrier concentration peak 211-1 may be provided, and the carrier concentration peak 211-2 does not need to be provided. For example, the carrier concentration peak 211-1 and the carrier concentration peak 211-2 may be provided at an end portion of the active collector region 22 in the top view (that is, a region closest to the edge termination structure portion 90). In at least a partial region set apart from the end portion of the active collector region 22, the carrier concentration peak 211-1 may be provided, and the carrier concentration peak 211-2 does not need to be provided. In the top view of the active collector region 22, an area of the region where the carrier concentration peak 211-2 is provided may be larger than, the same as, or smaller than an area of the region where the carrier concentration peak 211-2 is not provided.

As shown in FIG. 6, the edge collector region 122 has one or more edge peaks 221 that are each a chemical concentration peak of a P type dopant in the depth direction. The edge collector region 122 may alternatively have two or more edge peaks 221. In the example of FIG. 6, the edge collector region 122 has only one edge peak 221.

As shown in FIG. 6, the edge collector region 122 has one or more carrier concentration peaks 231 in the depth direction. The edge collector region 122 may alternatively have two or more carrier concentration peaks 231. In the example of FIG. 6, the edge collector region 122 has only one carrier concentration peak 231.

The carrier concentration peak 231 may be arranged at the same depth position as the edge peak 221. Note that the position of the carrier concentration peak 231 may contain an error with respect to the position of the edge peak 221. In the example of FIG. 6, the depth position of the carrier concentration peak 231 is arranged between the depth position Z1 of the edge peak 221 and the lower surface 23. A distance between the depth position of the corresponding carrier concentration peak 231 and the depth position of the edge peak 221 may be 0.05 μm or less, 0.03 μm or less, or 0.02 μm or less. A value (ratio) obtained by dividing the depth position of the corresponding carrier concentration peak 231 (the distance from the lower surface 23) by the depth position of the edge peak 221 (the distance from the lower surface 23) may be 200% or less, 150% or less, 100% or less, 50% or less, or 20% or less. In the example of FIG. 6, the depth position of the edge peak 221 is set as the depth position Z1 that is the same as that of the active peak 201-1, but the depth position of the edge peak 221 may differ from that of the active peak 201-1.

At least one active peak 201 may be arranged farther away from the lower surface 23 than any of the edge peaks 221. In the examples of FIGS. 5 and 6, the active peak 201-2 is arranged farther away from the lower surface 23 than any of the edge peaks 221. Accordingly, the active collector region 22 has the carrier concentration peak 211 at a position deeper than the edge collector region 122. Thus, the hole implantation efficiency of the active collector region 22 can be raised.

A distance between the edge peak 221 arranged farthest from the lower surface 23 out of the edge peaks 221 and the lower surface 23 is set as Z1. Further, a distance between the active peak 201-2 arranged farthest from the lower surface 23 out of the active peaks 201 and the lower surface 23 is set as Z2. The distance Z2 may be 2 times or more, 3 times or more, or 5 times or more of the distance Z1.

The number of active peaks 201 provided in the active collector region 22 in the depth direction may be larger than the number of edge peaks 221 provided in the edge collector region 122 in the depth direction. In the examples of FIGS. 5 and 6, the number of active peaks 201 is two, and the number of edge peaks 221 is one. Note that the numbers of peaks are not limited to these. By providing many active peaks 201, it becomes easy to increase the integrated value I1 of the carrier concentration in the active collector region 22, and to form the active collector region 22 to the vicinity of the drift region 18. Thus, the hole implantation efficiency of the active collector region 22 can be raised. The number of active peaks 201 may be 2 times or more of the number of edge peaks 221.

A value obtained by dividing the carrier concentration at each depth position by the chemical concentration of the dopant at the same depth position is used as an activation rate of the dopant at the depth position. Further, a value obtained by dividing the carrier concentration at a local maximum of the carrier concentration peak by the dopant concentration at the local maximum of the corresponding dopant concentration peak is used as an activation rate of the dopant at the peak of the dopant concentration (or the corresponding carrier concentration peak).

In the example of FIG. 5, the dopant concentrations at the local maximums of the active peak 201-1 and the active peak 201-2 are respectively represented by D1 and D2. Further, the carrier concentrations of the carrier concentration peak 211-1 and the carrier concentration peak 211-2 are respectively represented by C1 and C2. The activation rates of the active peak 201-1 and the carrier concentration peak 211-1 are C1/D1, and the activation rates of the active peak 201-2 and the carrier concentration peak 211-2 are C2/D2.

In the example of FIG. 6, the dopant concentration at the local maximum of the edge peak 221 is represented by D1 that is the same as the active peak 201-1. Note that the dopant concentration at the local maximum of the edge peak 221 may differ from the dopant concentration at the local maximum of the active peak 201-1. Moreover, the carrier concentration of the carrier concentration peak 231 is represented by C1 that is the same as the carrier concentration peak 211-1. Note that the carrier concentration at the local maximum of the carrier concentration peak 231 may differ from the carrier concentration at the local maximum of the carrier concentration peak 211-1. The activation rates of the edge peak 221 and the carrier concentration peak 231 are C1/D1.

Alternatively, the activation rate may be calculated using an integrated concentration. For example, in the active collector region 22, a value (nC1/nD1) obtained by dividing a value nC1 obtained by integrating the carrier concentration from the depth position 0 to the depth position Zu2 by a value nD1 obtained by integrating the dopant concentration from the depth position 0 to the depth position Zu2 may be used as the activation rate of the dopant in the active peak 201-1 of the dopant concentration (or the carrier concentration peak 211-1). Alternatively, in the edge collector region 122, a value (nC3/nD3) obtained by dividing a value nC3=I2 obtained by integrating the carrier concentration of the carrier concentration peak 231 from the depth position 0 to the depth position Zu2 by a value nD3 obtained by integrating the dopant concentration of the edge peak 221 from the depth position 0 to the depth position Zu2 may be used as the activation rate of the dopant in the edge peak 221 of the dopant concentration (or the carrier concentration peak 231). A value (nC2/nD2) obtained by dividing a value nC2=I1b obtained by integrating the carrier concentration of the carrier concentration peak 211-2 from the depth position Zu2 to the depth position Zu1 by a value nD2 obtained by integrating the dopant concentration of the active peak 201-2 from the depth position Zu2 to the depth position Zu1 may be used as the activation rate of the dopant in the active peak 201-2 of the dopant concentration (or the carrier concentration peak 211-2).

The activation rate of the dopant in the active collector region 22 and the activation rate of the dopant in the edge collector region 122 may differ. As the activation rate in each collector region, an average value of activation rates at the respective depth positions in each collector region may be used. For example, a value obtained by dividing a value obtained by integrating the activation rate across the depth range of the active collector region 22 (0 to Zu1) by the length Zu1 of the depth range may be used as the activation rate of the active collector region 22. Further, a value obtained by dividing a value obtained by integrating the activation rate across the depth range of the edge collector region 122 (0 to Zu2) by the length Zu2 of the depth range may be used as the activation rate of the edge collector region 122.

In this example, the activation rate of the dopant in the active collector region 22 is higher than the activation rate of the dopant in the edge collector region 122. Accordingly, it becomes easy to increase the integrated value I1 of the carrier concentration in the active collector region 22 and raise the hole implantation efficiency. The activation rate in the active collector region 22 may be 2 times or more, 5 times or more, or 10 times or more of the activation rate in the edge collector region 122.

The activation rate of any active peak 201 may be the same as the activation rate of any edge peak 221. The activation rates of the active peak 201 and the edge peak 221 arranged at the same depth position may be the same. In the examples of FIGS. 5 and 6, the activation rate C1/D1 of the active peak 201-1 and the activation rate C1/D1 of the edge peak 221 are the same. By forming the carrier concentration peak 211-1 and the carrier concentration peak 231 by the same manufacturing process, these activation rates can be made the same. For example, by simultaneously implanting dopant ions at a uniform dose amount across the entire lower surface 23 of the semiconductor substrate 10 and annealing the entire semiconductor substrate 10, the carrier concentration peak 211-1 and the carrier concentration peak 231 having the same activation rate can be formed. Note that the activation rate of the active peak 201-1 (or the carrier concentration peak 211-1) and the activation rate of the edge peak 221 (or the carrier concentration peak 231) may differ.

The activation rate of any of the active peaks 201 may be larger than the activation rate of any of the edge peaks 221. The activation rate of any of the active peaks 201 may be larger than the activation rate of any of the edge peaks 221 arranged closer to the lower surface 23 than the active peak 201. The activation rate of the active peak 201 arranged farthest from the lower surface 23 out of the one or more active peaks 201 may be larger than the activation rate of the edge peak 221 arranged closest to the lower surface 23 out of the one or more edge peaks 221. In the examples of FIGS. 5 and 6, the activation rate of the active peak 201-2 (for example, C2/D2) is larger than the activation rates of the active peak 201-1 and the edge peak 221 (for example, C1/D1). By increasing the activation rate of the active peak 201-2 (for example, C2/D2), it is possible to increase the integrated value I1 of the carrier concentration of the active collector region 22 and raise the hole implantation efficiency of the active collector region 22. For example, by locally implanting dopant ions into a region where the active collector region 22 is to be formed and performing furnace annealing or laser annealing at a relatively high temperature, the carrier concentration peak 211-2 having a high activation rate (for example, C2/D2) can be formed. After that, by implanting dopant ions into a region where the carrier concentration peak 211-1 and the carrier concentration peak 231 are to be formed and performing furnace annealing at a relatively low temperature, the carrier concentration peak 211-1 and the carrier concentration peak 231 having low activation rates (for example, C1/D1) can be formed.

The maximum activation rate out of the activation rates of the active peaks 201 (for example, the activation rate C2/D2) may be 2 times or more, 5 times or more, 10 times or more, or 50 times or more of the maximum activation rate out of the activation rates of the edge peaks 221 (for example, the activation rate C1/D1). The maximum activation rate out of the activation rates of the active peaks 201 (for example, the activation rate C2/D2) may be 0.8 (80%) or more, 0.85 (85%) or more, or 0.9 (90%) or more. The maximum activation rate out of the activation rates of the active peaks 201 (for example, the activation rate C2/D2) is 1 (100%) or less. Further, the maximum activation rate out of the activation rates of the edge peaks 221 (for example, the activation rate C1/D1) may be 0.1 (10%) or less, 0.05 (5%) or less, 0.01 (1%) or less, or 0.005 (0.5%) or less. The maximum activation rate out of the activation rates of the edge peaks 221 (for example, the activation rate C1/D1) may be 0.001 or more.

The activation rate of the dopant may be 10% or less in at least one of the active peak 201 (or the carrier concentration peak 211) included in the active collector region 22 or the edge peak 221 (or the carrier concentration peak 231) included in the edge collector region 122.

By forming the carrier concentration peak having a small activation rate, a region where the chemical concentration of the dopant is high and the carrier concentration is low can be formed. With a low chemical concentration of the dopant, the dose amount of the dopant becomes small, and a ratio of an error component to the dose amount becomes large. By forming a carrier concentration peak having a small activation rate, a concentration of a region having a low carrier concentration can be controlled accurately.

The activation rate in at least one edge peak 221 may be 10% or less. In the example of FIG. 6, the activation rate of the edge peak 221 in contact with the lower surface 23 is 10% or less. The activation rate of the peak may be 5% or less, 1% or less, or 0.5% or less. Accordingly, the integrated value I2 can be controlled accurately while decreasing the integrated value I2 of the carrier concentration of the edge collector region 122 to thus lower the hole implantation efficiency of the edge collector region 122. In addition, it is possible to set the chemical concentration of the dopant of the edge peak 221 high, and make contact resistance between the collector electrode 24 and the edge collector region 122 small.

The activation rate in at least one active peak 201 may be 10% or less. In the example of FIG. 5, the activation rate of the active peak 201-1 in contact with the lower surface 23 is 10% or less. The activation rate of the peak may be 5% or less, 1% or less, or 0.5% or less. By lowering the activation rate of the active peak 201-1 in contact with the lower surface 23, the chemical concentration of the dopant of the active peak 201-1 can be increased, and contact resistance between the collector electrode 24 and the active collector region 22 can be made small.

The active collector region 22 may have two active peaks 201 having different activation rates of the dopant. In the example of FIG. 5, the activation rate differs between the active peak 201-1 and the active peak 201-2 as described above. The activation rates of the active peak 201-1 and the active peak 201-2 may differ by 10 times or more. The activation rates of the active peak 201-1 and the active peak 201-2 may differ by 50 times or more.

The activation rate in any one of the two or more active peaks 201 in the active collector region 22 may be lower than the activation rate in the active peak 201 arranged at a position farther away from the lower surface 23. In the example of FIG. 5, the activation rate of the active peak 201-1 is lower than the activation rate of the active peak 201-2. Accordingly, the contact resistance between the collector electrode 24 and the active collector region 22 can be made small while controlling the integrated value I1 of the carrier concentration to be within a predetermined range.

As shown in FIG. 5, pulse widths of the active peak 201-1, the active peak 201-2, the carrier concentration peak 211-1, and the carrier concentration peak 211-2 are respectively represented by W01, W02, W11, and W12. As shown in FIG. 6, pulse widths of the edge peak 221 and the carrier concentration peak 231 are respectively represented by W21 and W31. The pulse width of a peak is a length of a region where a concentration becomes a predetermined value or more in the peak, in the depth direction. The predetermined value is a value obtained by multiplying a concentration at a local maximum of a peak by a predetermined coefficient α. α may be 0.5 or 0.1, or may take other values. The coefficient α is common to the respective peaks.

For example, the pulse width W01 of the active peak 201-1 is a length of a region where the chemical concentration of the dopant becomes α×D1 or more in the active peak 201-1, in the depth direction. The pulse width W01 of the active peak 201-1 may alternatively be a value obtained by doubling a distance (W01/2) from the depth position Z1 of the local maximum of the peak to a depth position at which the chemical concentration of the dopant becomes α×D1 on the upper surface 21 side. Similarly for the pulse widths of other peaks, a value obtained by doubling a distance from a depth position of a local maximum of a peak to a depth position at which the concentration becomes a predetermined value may be used.

The active collector region 22 may have the first carrier concentration peak (the carrier concentration peak 211-1 in this example) and the second carrier concentration peak (the carrier concentration peak 211-2 in this example) arranged farther away from the lower surface 23 than the first carrier concentration peak. The peak width W12 of the carrier concentration peak 211-2 may be 2 times or more of the peak width W11 of the carrier concentration peak 211-1. Accordingly, the integrated value I1 of the carrier concentration in the active collector region 22 can be made large, and the upper end position Zu1 of the active collector region 22 can be set apart from the lower surface 23. Thus, the hole implantation efficiency of the active collector region 22 can be raised. The peak width W12 may be 5 times or more or 10 times or more of the peak width W11.

The peak width W02 of the active peak 201-2 may be 2 times or more of the peak width W01 of the active peak 201-1. Accordingly, the integrated value I1 of the carrier concentration in the active collector region 22 can be made large, and the upper end position Zu1 of the active collector region 22 can be set apart from the lower surface 23. Thus, the hole implantation efficiency of the active collector region 22 can be raised. The peak width W02 may be 5 times or more or 10 times or more of the peak width W01.

The peak width of any of the carrier concentration peaks 211 in the active collector region 22 may be larger than the peak width of any of the carrier concentration peaks 231 in the edge collector region 122. Any of the carrier concentration peaks 211 may have a larger peak width than the carrier concentration peak 231 arranged closer to the lower surface 23 than the carrier concentration peak 211. In the examples of FIGS. 5 and 6, the peak width W12 of the carrier concentration peak 211-2 in the active collector region 22 is larger than the peak width W31 of the carrier concentration peak 231 in the edge collector region 122. The peak width W12 of the carrier concentration peak 211-2 in the active collector region 22 may be 2 times or more of the peak width W31 of the carrier concentration peak 231 in the edge collector region 122. Accordingly, the integrated value I1 of the carrier concentration in the active collector region 22 can be made large, and the upper end position Zu1 of the active collector region 22 can be set apart from the lower surface 23. Thus, the hole implantation efficiency of the active collector region 22 can be raised. The peak width W12 may be 5 times or more or 10 times or more of the peak width W31.

The peak width W02 of the active peak 201-2 may be 2 times or more of the peak width W21 of the edge peak 221. Accordingly, the integrated value I1 of the carrier concentration in the active collector region 22 can be made large, and the upper end position Zu1 of the active collector region 22 can be set apart from the lower surface 23. Thus, the hole implantation efficiency of the active collector region 22 can be raised. The peak width W02 may be 5 times or more or 10 times or more of the peak width W21.

The active collector region 22 may have an active peak 201 formed by a different dopant ion. In the example of FIG. 5, the active peak 201-1 and the active peak 201-2 may be formed by implanting different dopant ions. Accordingly, the activation rates of peaks can be easily differentiated. Further, the pulse widths of the respective peaks can be easily differentiated. The dopant ions of the active peak 201-1 may be ions that are more difficult to be activated than the dopant ions of the active peak 201-2. Moreover, the dopant ions of the active peak 201-1 may be implanted into the semiconductor substrate 10 with a higher acceleration energy than the dopant ions of the active peak 201-2. As the acceleration energy increases, the variation in projected range of dopant ions becomes smaller, and the pulse width can thus be made smaller.

In this example, BF₂ ions are implanted to form the active peak 201-1 and the edge peak 221. Moreover, boron ions are implanted to form the active peak 201-2. Accordingly, the activation rates of the active peak 201-1 and the edge peak 221 can be easily made to be lower than the active peak 201-2. Furthermore, the pulse width of the active peak 201-2 can be easily increased. The edge collector region 122 of this example contains fluorine since BF₂ ions are implanted. Similarly, the active collector region 22 of this example also contains fluorine. In the active collector region 22 of this example, a fluorine concentration of a region where the active peak 201-1 is provided is higher than a fluorine concentration of a region where the active peak 201-2 is provided.

The carrier concentration C1 of the carrier concentration peak 211-1 may be higher than the carrier concentration C2 of the carrier concentration peak 211-2. The carrier concentration C1 and the carrier concentration C2 may each be 1×10¹⁷/cm³ or more or 1×10¹⁸/cm³ or more. The carrier concentration C1 may be 10 times or less, 5 times or less, or 2 times or less of the carrier concentration C2.

The dopant concentration D1 of the active peak 201-1 is higher than the dopant concentration D2 of the active peak 201-2. The dopant concentration D1 may be 10 times or more, 50 times or more, or 100 times or more of the dopant concentration D2. The dopant concentration D1 may be 1,000 times or less of the dopant concentration D2. The dopant concentration D1 may be 1×10¹⁹ atoms/cm³ or more, 5×10¹⁹ atoms/cm³ or more, or 1×10²⁰ atoms/cm³ or more. The dopant concentration D1 may be 1×10²² atoms/cm³ or less or 1×10²¹ atoms/cm³ or less. The dopant concentration D2 may be smaller than 1×10¹⁹ atoms/cm³, or may be 5×10¹⁸ atoms/cm³ or less or 1×10¹⁸ atoms/cm³ or less. The dopant concentration D2 may be 1×10¹⁶ atoms/cm³ or more, 1×10¹⁷ atoms/cm³ or more, or 5×10¹⁷ atoms/cm³ or more.

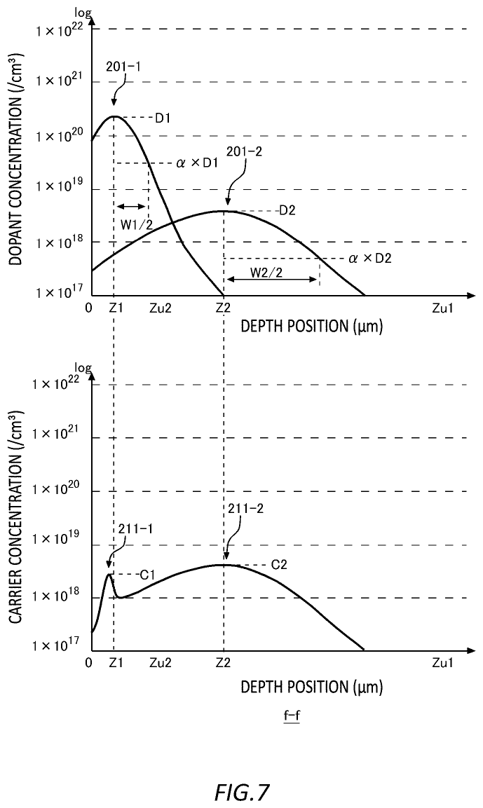

FIG. 7 illustrates a view showing another example of the distribution of the dopant concentration and the carrier concentration in the active collector region 22. In the active collector region 22 of this example, the carrier concentration C2 of the carrier concentration peak 211-2 is higher than the carrier concentration C1 of the carrier concentration peak 211-1. Other structures are similar to any of the examples described in the present specification. Accordingly, it is possible to increase the carrier concentration of the region set apart from the lower surface 23 and raise the hole implantation efficiency of the active collector region 22. The carrier concentration C2 may be 1.2 times or more, 1.5 times or more, 2 times or more, or 5 times or more of the carrier concentration C1. The carrier concentration C1 and the carrier concentration C2 may each be 1×10¹⁷/cm³ or more or 1×10¹⁸/cm³ or more.

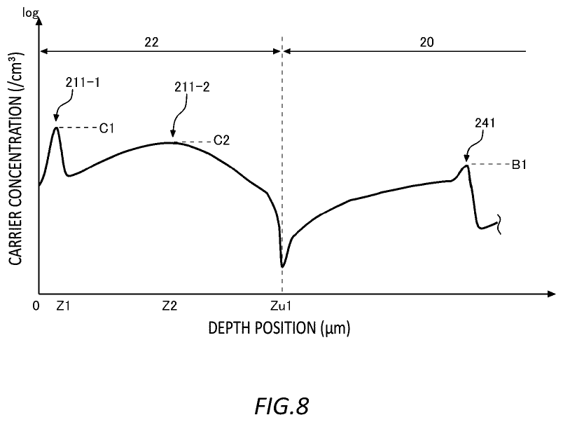

FIG. 8 illustrates a view showing an example of the carrier concentration distribution in the active collector region 22 and a part of the buffer region 20. The carrier concentration distribution in the active collector region 22 is similar to any of the examples described in the present specification.

The buffer region 20 is arranged in contact with the upper end of the active collector region 22 in the semiconductor substrate 10. As described above, a PN junction is provided at the depth position Zu1 of the boundary between the active collector region 22 and the buffer region 20. The buffer region 20 has one or more carrier concentration peaks 241 in the depth direction. FIG. 8 shows only one carrier concentration peak 241 closest to the active collector region 22, and omits other carrier concentration peaks 241.

Of the carrier concentration peaks 211 of the active collector region 22, the carrier concentration peak 211-2 is arranged closest to the buffer region 20. The carrier concentration C2 of the carrier concentration peak 211-2 may be 10 times or more of a carrier concentration B1 of the carrier concentration peak 241. By setting the carrier concentration C2 of the carrier concentration peak 211-2 high, the hole implantation efficiency of the active collector region 22 can be raised. The carrier concentration C2 may be 20 times or more or 50 times or more of the carrier concentration B1. The carrier concentration B1 may be a maximum value of the carrier concentrations in the buffer region 20.

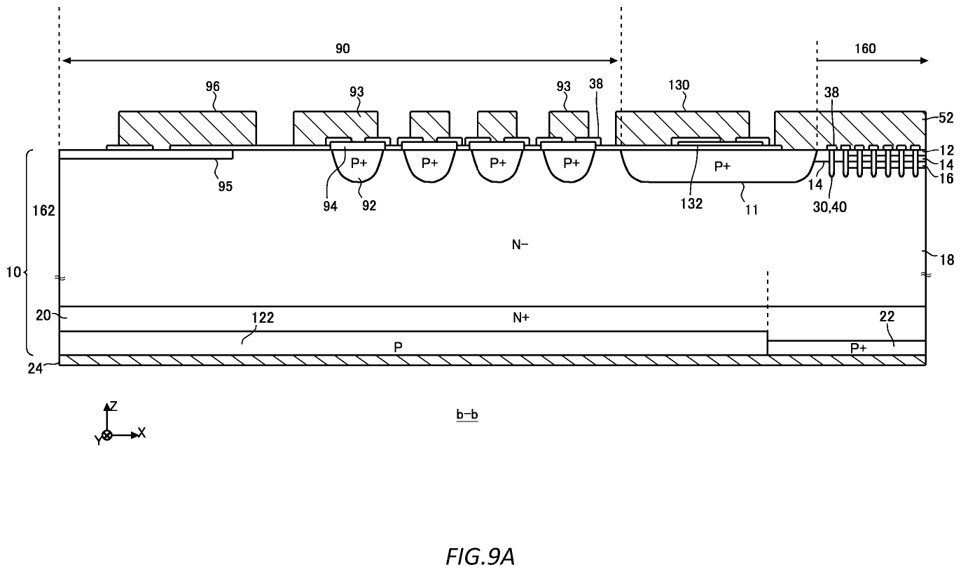

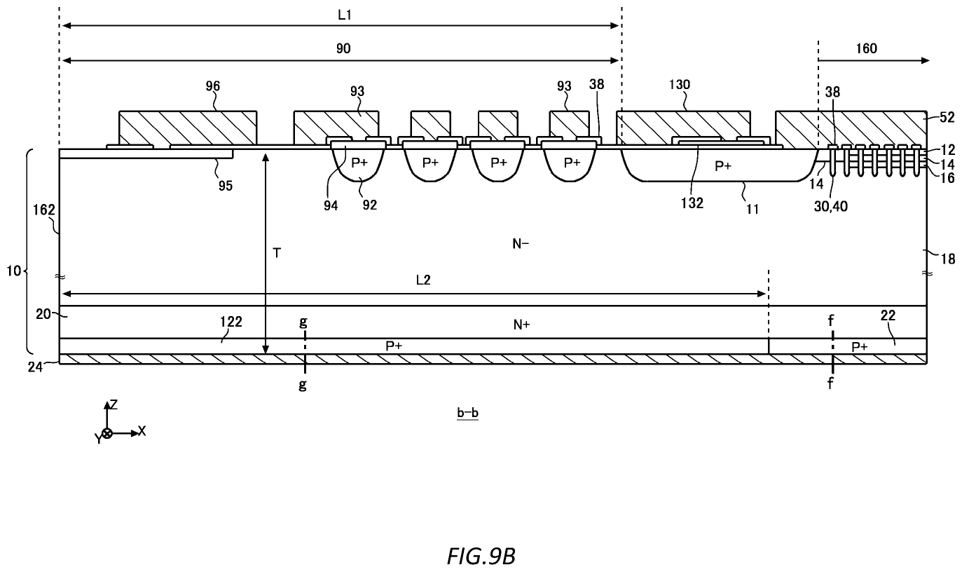

FIG. 9A illustrates a view showing another example of the cross section b-b. In this example, the upper end position of the edge collector region 122 (Zu2 in FIG. 6) is farther away from the lower surface 23 than the upper end position of the active collector region 22 (Zu1 in FIG. 5). Other structures are similar to any of the examples described in the present specification. Also in this example, the integrated value I1 of the carrier concentration in the active collector region 22 is larger than the integrated value I2 of the carrier concentration in the edge collector region 122. In this example, the peak concentration C1 of the carrier concentration peak 231 in the edge collector region 122 is lower than the peak concentration C2 of the carrier concentration peak 211-2 in the active collector region 22. The peak concentration C1 may be 50% or less, 30% or less, or 10% or less of the peak concentration C2.

FIG. 9B illustrates a view showing another example of the cross section b-b. In this example, the upper end position of the edge collector region 122 (Zu2 in FIG. 6) and the upper end position of the active collector region 22 (Zu1 in FIG. 5) are the same. Other structures are similar to any of the examples described in the present specification. Also in this example, the integrated value I1 of the carrier concentration in the active collector region 22 is larger than the integrated value I2 of the carrier concentration in the edge collector region 122. In this example, the peak concentration C1 of the carrier concentration peak 231 in the edge collector region 122 is lower than the peak concentration C2 of the carrier concentration peak 211-2 in the active collector region 22. The peak concentration C1 may be 50% or less, 30% or less, or 10% or less of the peak concentration C2.

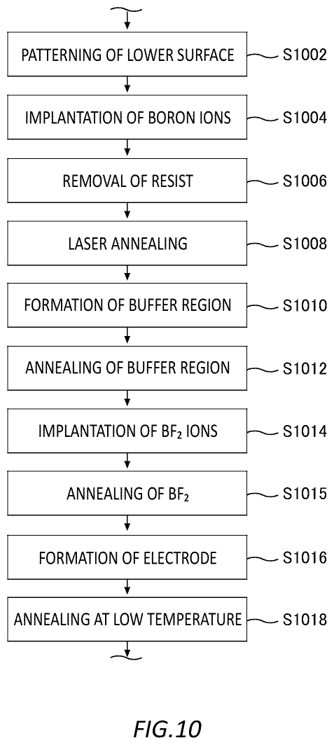

FIG. 10 is a flowchart showing an example of a manufacturing method of the semiconductor device 100. In the manufacturing processes of this example, BF₂ ions are implanted into a region where the edge collector region 122 is to be formed from the lower surface of the semiconductor substrate 10, and processes after the implantation of BF₂ ions are performed at 3000 or less. Accordingly, the carrier concentration peak 231 having a low activation rate can be formed in the edge collector region 122. The semiconductor substrate 10 may be annealed at 3000 or less after the implantation of BF₂ ions. The annealing temperature may be 2800 or less or 2600 or less.

In the process of implanting BF₂ ions into the edge collector region 122, BF₂ ions may also be implanted into the active collector region 22. Accordingly, the carrier concentration peak 211-1 having a low activation rate can be formed in the active collector region 22. Moreover, before the implantation of BF₂ ions, dopant ions such as boron ions may be implanted into the active collector region 22, and the semiconductor substrate 10 may be annealed at a higher temperature than 3000. Accordingly, the carrier concentration peak 211-2 having a high activation rate can be formed in the active collector region 22. The annealing temperature may be 3300 or more, 3600 or more, or 4000 or more.

FIG. 10 shows some processes of the manufacturing method of the semiconductor device 100. The structure on the upper surface 21 side of the semiconductor device 100 may be formed before the processes shown in FIG. 10. Further, before the processes shown in FIG. 10, the semiconductor substrate 10 may be thinned in accordance with the breakdown voltage that the semiconductor device 100 should have.

In the example of FIG. 10, in Step S1002, a resist mask is formed on the lower surface 23 of the semiconductor substrate 10, and patterning of the resist mask is performed. The resist mask covers regions other than the region where the active collector region 22 is to be formed.

Next, in Step S1004, dopant ions such as boron ions are implanted into the region not covered by the mask (that is, the region where the active collector region 22 is to be formed). In Step S1004, boron ions are implanted at the depth position Z2 at which the active peak 201-2 is to be formed. Next, in Step S1006, the resist mask on the lower surface 23 is removed.

Next, in Step S1008, the semiconductor substrate 10 is annealed. In Step S1008, the region implanted with the boron ions or the like may be selectively annealed by laser annealing, or the entire semiconductor substrate 10 may be annealed by an annealing furnace or the like. The annealing temperature in Step S1008 may be higher than 3000 as described above, and may be 3300 or more, 3600 or more, or 4000 or more. Accordingly, the carrier concentration peak 211-2 having a high activation rate can be formed.

Next, in Step S1010, the buffer region 20 is formed. In Step S1010, a proton, phosphorus ions, or the like may be implanted from the lower surface 23 of the semiconductor substrate 10. Next, in Step S1012, the semiconductor substrate 10 is annealed. Accordingly, the buffer region 20 can be formed.

Next, in Step S1014, BF₂ ions are implanted across the entire lower surface 23 of the semiconductor substrate 10. BF₂ ions are implanted at the depth position Z1. As described above, the processes after Step S1014 are performed at a temperature lower than 3000. For example, in Step S1015, the semiconductor substrate 10 may be annealed at a temperature of 3000 or less or a temperature lower than 3000. Accordingly, the carrier concentration peak 211-1 and the carrier concentration peak 231 having low activation rates can be formed. Step S1015 may be omitted. Step S1014 may be performed before Step S1012. In this case, the annealing temperature in Step S1012 is 3000 or less.

Next, in Step S1016, the collector electrode 24 is formed. The collector electrode 24 may be formed by sputtering. Next, in Step S1018, the semiconductor substrate 10 is annealed. The annealing temperature in Step S1018 may be 3000 or less or lower than 3000 as described above, and may be 2800 or less or 2600 or less. Accordingly, BF₂ ions can be activated so as to form the carrier concentration peak 211-1 and the carrier concentration peak 231.

Ion implantation for lifetime control and annealing for lifetime control may be performed between Step S1012 and Step S1014. The ion implantation for lifetime control may be implantation of hydrogen ions or implantation of helium ions. A processing temperature in the annealing for lifetime control may be similar to or lower than the temperature for forming the buffer region in Step S1012. The processing temperature in the annealing for lifetime control may be a temperature higher than that of Step S1014 or processes after that.

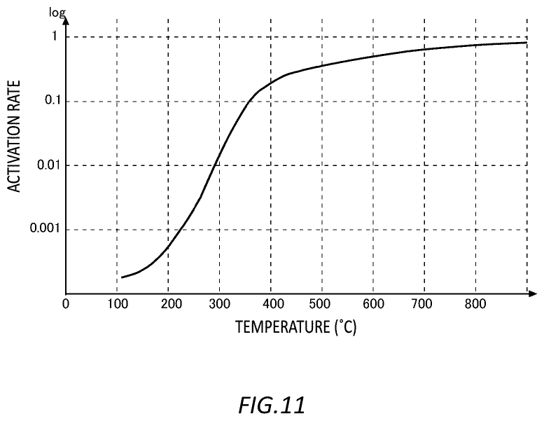

FIG. 11 illustrates a view showing an example of a relationship between the annealing temperature of the semiconductor substrate 10 and the activation rate of the dopant. The dopant ions in this example are BF₂ ions, but also for other dopant ions, the activation rate fluctuates according to the annealing temperature.

As shown in FIG. 11, the activation rate increases as the annealing temperature increases. Thus, by adjusting the annealing temperature, the activation rates of the respective carrier concentration peaks can be adjusted. In the example of FIG. 11, by setting the annealing temperature to be 3000 or less, the activation rate is sufficiently smaller than 0.1.

While the present invention has been described by way of the embodiments above, the technical scope of the present invention is not limited to the above described embodiments. It is apparent to persons skilled in the art that various alterations or improvements can be made to the above described embodiments. It is also apparent from the description of the claims that embodiments added with such alterations or improvements can be included in the technical scope of the present invention.

The operations, procedures, steps, and stages of each process performed by an apparatus, system, program, and method illustrated in the claims, embodiments, or diagrams can be performed in any order as long as the order is not indicated by “prior to,” “before,” or the like and as long as the output from a previous process is not used in a later process. Even if the operation flow is described by using phrases such as “first” or “next” in the scope of the claims, specification, or drawings, it does not necessarily mean that the process must be performed in this order.

What is claimed is:

1. A semiconductor device including a semiconductor substrate which has an upper surface and a lower surface and includes a drift region of a first conductivity type, comprising:
an upper surface electrode arranged above the upper surface of the semiconductor substrate;
an active portion arranged below the upper surface electrode in the semiconductor substrate; and
an edge termination structure portion arranged between the upper surface electrode and an end side of the semiconductor substrate in a top view, in the semiconductor substrate, wherein
the active portion includes an active collector region of a second conductivity type, which is arranged between the lower surface and the drift region in the semiconductor substrate,
the edge termination structure portion includes an edge collector region of the second conductivity type, which is arranged between the lower surface and the drift region in the semiconductor substrate,
an integrated value of a carrier concentration of the active collector region in a depth direction of the semiconductor substrate is larger than an integrated value of a carrier concentration of the edge collector region in the depth direction, and
an upper end position of the active collector region in the depth direction and an upper end position of the edge collector region in the depth direction differ.

2. The semiconductor device according to claim 1, wherein
the upper end position of the active collector region is farther away from the lower surface of the semiconductor substrate than the upper end position of the edge collector region.

3. The semiconductor device according to claim 1, wherein
the active collector region has one or more active peaks that are each a chemical concentration peak of a dopant of the second conductivity type in the depth direction,
the edge collector region has one or more edge peaks that are each a chemical concentration peak of a dopant of the second conductivity type in the depth direction, and
at least one of the active peaks is arranged farther away from the lower surface than any of the edge peaks.

4. The semiconductor device according to claim 1, wherein
the active collector region has two or more active peaks that are each a chemical concentration peak of a dopant of the second conductivity type in the depth direction,
the edge collector region has one or more edge peaks that are each a chemical concentration peak of a dopant of the second conductivity type in the depth direction, and
a number of the active peaks is larger than a number of the edge peaks.

5. The semiconductor device according to claim 1, wherein
an average value of activation rates of a dopant in the active collector region and an average value of activation rates of a dopant in the edge collector region differ.

6. The semiconductor device according to claim 5, wherein
the average value of the activation rates of the dopant in the active collector region is higher than the average value of the activation rates of the dopant in the edge collector region.

7. The semiconductor device according to claim 1, wherein
the active collector region has one or more active peaks that are each a chemical concentration peak of a dopant of the second conductivity type in the depth direction,
the edge collector region has one or more edge peaks that are each a chemical concentration peak of a dopant of the second conductivity type in the depth direction, and
an activation rate of the dopant is 10% or less in at least one peak out of the one or more active peaks and the one or more edge peaks.

8. The semiconductor device according to claim 7, wherein
the activation rate is 10% or less in at least one of the edge peaks.

9. The semiconductor device according to claim 1, wherein
the active collector region has one or more active peaks that are each a chemical concentration peak of a dopant of the second conductivity type in the depth direction, and
an activation rate of the dopant is 10% or less in at least one of the active peaks.

10. The semiconductor device according to claim 1, wherein
the active collector region has two or more active peaks that are each a chemical concentration peak of a dopant of the second conductivity type in the depth direction, and
the two or more active peaks include two of the active peaks having different activation rates of the dopant.

11. The semiconductor device according to claim 10, wherein
the activation rates in the two of the active peaks differ by 10 times or more.

12. The semiconductor device according to claim 10, wherein
the activation rate in any one of the two or more active peaks is lower than the activation rate in the active peak arranged at a position farther away from the lower surface than the any one of the two or more active peaks.

13. The semiconductor device according to claim 1, wherein
the edge collector region contains fluorine.

14. The semiconductor device according to claim 13, wherein
the active collector region contains fluorine.

15. The semiconductor device according to claim 1, wherein
the active collector region has a first carrier concentration peak and a second carrier concentration peak that is arranged farther away from the lower surface than the first carrier concentration peak and has a higher concentration than the first carrier concentration peak.

16. The semiconductor device according to claim 1, wherein
the active collector region has a first carrier concentration peak and a second carrier concentration peak arranged farther away from the lower surface than the first carrier concentration peak, and
a peak width of the second carrier concentration peak is 2 times or more of a peak width of the first carrier concentration peak.

17. The semiconductor device according to claim 1, wherein
the active collector region has two or more carrier concentration peaks in the depth direction,
the semiconductor substrate includes a buffer region of the first conductivity type, which is arranged in contact with an upper end of the active collector region and has one or more carrier concentration peaks in the depth direction, and
a carrier concentration of the carrier concentration peak closest to the buffer region out of the carrier concentration peaks of the active collector region is 10 times or more of a carrier concentration of the carrier concentration peak closest to the active collector region out of the carrier concentration peaks of the buffer region.

18. A semiconductor device including a semiconductor substrate which has an upper surface and a lower surface and includes a drift region of a first conductivity type, comprising:
an upper surface electrode arranged above the upper surface of the semiconductor substrate;
an active portion arranged below the upper surface electrode in the semiconductor substrate; and
an edge termination structure portion arranged between the upper surface electrode and an end side of the semiconductor substrate in a top view, in the semiconductor substrate, wherein
the active portion includes an active collector region of a second conductivity type, which is arranged between the lower surface and the drift region in the semiconductor substrate,
the edge termination structure portion includes an edge collector region of the second conductivity type, which is arranged between the lower surface and the drift region in the semiconductor substrate, and
an average value of activation rates of a dopant in the active collector region and an average value of activation rates of a dopant in the edge collector region differ.

19. A semiconductor device including a semiconductor substrate which has an upper surface and a lower surface and includes a drift region of a first conductivity type, comprising:
an upper surface electrode arranged above the upper surface of the semiconductor substrate;
an active portion arranged below the upper surface electrode in the semiconductor substrate; and
an edge termination structure portion arranged between the upper surface electrode and an end side of the semiconductor substrate in a top view, in the semiconductor substrate, wherein
the active portion includes an active collector region of a second conductivity type, which is arranged between the lower surface and the drift region in the semiconductor substrate,
the edge termination structure portion includes an edge collector region of the second conductivity type, which is arranged between the lower surface and the drift region in the semiconductor substrate,
the active collector region has one or more active peaks that are each a chemical concentration peak of a dopant of the second conductivity type in a depth direction of the semiconductor substrate,
the edge collector region has one or more edge peaks that are each a chemical concentration peak of a dopant of the second conductivity type in the depth direction, and
an activation rate of the dopant is 10% or less in at least one of peaks included in the one or more active peaks and the one or more edge peaks.

20. A semiconductor device including a semiconductor substrate which has an upper surface and a lower surface and includes a drift region of a first conductivity type, comprising:
an upper surface electrode arranged above the upper surface of the semiconductor substrate; and
an active portion arranged below the upper surface electrode in the semiconductor substrate, wherein
the active portion includes an active collector region of a second conductivity type, which is arranged between the lower surface and the drift region in the semiconductor substrate,
the active collector region has two or more active peaks that are each a chemical concentration peak of a dopant of the second conductivity type in a depth direction of the semiconductor substrate, and
the two or more active peaks include two of the active peaks having different activation rates of the dopant.

21. A manufacturing method of a semiconductor device including a semiconductor substrate which has an upper surface and a lower surface and includes a drift region of a first conductivity type, the semiconductor device including:
an upper surface electrode arranged above the upper surface of the semiconductor substrate;
an active portion arranged below the upper surface electrode in the semiconductor substrate; and
an edge termination structure portion arranged between the upper surface electrode and an end side of the semiconductor substrate in a top view, in the semiconductor substrate, wherein
the active portion includes an active collector region of a second conductivity type, which is arranged between the lower surface and the drift region in the semiconductor substrate,
the edge termination structure portion includes an edge collector region of the second conductivity type, which is arranged between the lower surface and the drift region in the semiconductor substrate, and
the manufacturing method of a semiconductor device comprises:
implanting BF₂ ions into a region where the edge collector region is to be formed; and
performing a process to be carried out after the implanting the BF₂ ions at 3000 or less.

22. The manufacturing method of a semiconductor device according to claim 21, wherein
the semiconductor substrate is annealed at 3000 or less after the implanting the BF₂ ions.

23. The manufacturing method of a semiconductor device according to claim 21, wherein
the implanting the BF₂ ions into the edge collector region includes implanting the BF₂ ions also into the active collector region.

24. The manufacturing method of a semiconductor device according to claim 22, wherein
dopant ions are implanted into the active collector region and the semiconductor substrate I annealed at a temperature higher than 3000, before the implanting the BF₂ ions.
